(19) United States
(12) Patent Application Publication
(10) Pub. No.: US 2020/0264953 A1
(43) Pub. Date: Aug. 20, 2020

(54) ERROR CORRECTION IN DATA STORAGE DEVICES

(71) Applicant: Western Digital Technologies, Inc., San Jose, CA (US)

(72) Inventor: Minghai QIN, San Jose, CA (US)

(21) Appl. No.: 16/281,039

(22) Filed: Feb. 20, 2019

(51) Int. Cl. G06F 11/10; H03M 13/11

(52) U.S. Cl. CPC G06F 11/1076; H03M 13/11

(57) ABSTRACT

Systems and methods are disclosed for error correction in data storage devices. In some implementations, a method is provided. The method includes obtaining configuration data indicating a logical arrangement for a set of blocks. The logical arrangement includes rows and columns of blocks. The configuration data also indicates a number of row parity blocks in a set of row parity blocks and a number of diagonal parity blocks in a set of diagonal parity blocks. The method also includes configuring a set of storage devices based on the configuration data, wherein a first number of data blocks in the set of diagonal parity blocks is less than a second number of data blocks in a column.

### BACKGROUND

### Field of the Disclosure

This disclosure relates to data storage devices. More particularly, the disclosure relates to error correction in data storage devices.

### Description of the Related Art

Data storage devices may be used to store data used by computing devices, users, other devices, etc. The data that is stored on the data storage devices may become inaccessible, corrupted, damaged, or may have errors. Various error correction and/or detection schemes, codes, algorithms, functions, operations, etc., maybe used to protect the data that is stored on the data storage devices, from loss.

### SUMMARY

In some implementations, the present disclosure relates to an apparatus. The apparatus includes a set of storage devices. The set of storage devices includes a set of blocks logically arranged in rows and columns. The set of blocks includes a set of data blocks, a set of row parity blocks, and a set of diagonal parity blocks. A first number of data blocks in the set of diagonal parity blocks is less than a second number of data blocks in a column. The apparatus also includes a processing device coupled to the set of storage devices. The processing device is configured to manage access to the set of storage devices.

In some implementations, the present disclosure relates to a method. The method includes obtaining configuration data indicating a logical arrangement for a set of blocks. The logical arrangement includes rows and columns of blocks. The configuration data also indicates a number of row parity blocks in a set of row parity blocks and a number of diagonal parity blocks in a set of diagonal parity blocks. The method also includes configuring a set of storage devices based on the configuration data. A first number of data blocks in the set of diagonal parity blocks is less than a second number of data blocks in a column.

In some implementations, the present disclosure relates to a non-transitory machine-readable medium. The non-transitory machine-readable medium has instructions stored therein, which when executed by a processor, cause the processor to perform various operations. The operations include obtaining configuration data. The configuration data indicates a logical arrangement for a set of blocks. The logical arrangement includes rows and columns of blocks. The configuration data also indicates a number of row parity blocks in a set of row parity blocks. The configuration data also indicates a number of diagonal parity blocks in a set of diagonal parity blocks. The operations also include configuring a set of storage devices based on the configuration data. A first number of diagonal parity blocks in the set of diagonal parity blocks is less than a second number of data blocks in a column.

### BRIEF DESCRIPTION OF THE DRAWINGS

FIG. 1 is a diagram illustrating an example data storage system, in accordance with one or more embodiments of the present disclosure.

FIG. 2 is a diagram illustrating an example data storage system, in accordance with one or more embodiments of the present disclosure.

FIG. 3 is a diagram illustrating an example data storage system, in accordance with one or more embodiments of the present disclosure.

FIG. 4 is a diagram illustrating an example data storage system, in accordance with one or more embodiments of the present disclosure.

FIG. 5 is a flowchart illustrating an example a process for configuring a data storage system, in accordance with one or more embodiments of the present disclosure.

FIG. 6 is a flowchart illustrating an example a process for recovering data blocks in a data storage system, in accordance with one or more embodiments of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following disclosure, reference is made to examples, implementations, and/or embodiments of the disclosure. However, it should be understood that the disclosure is not limited to specific described examples, implementations, and/or embodiments. Any combination of the features, functions, operations, components, modules, etc., disclosed herein, whether related to different embodiments or not, may be used to implement and practice the disclosure. Furthermore, although embodiments of the disclosure may provide advantages and/or benefits over other possible solutions, whether or not a particular advantage and/or benefit is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in the claim(s).

The headings provided herein are for convenience only and do not necessarily affect the scope or meaning of the claimed invention. Disclosed herein are example implementations, configurations, and/or embodiments relating to error correction for data storage devices.

Data storage devices, such as solid state drives (SSDs), hard disk drives (HDDs), hybrid drives (e.g., storage drives/devices that include both magnetic media/medium and flash memory), etc., typically include one or more controllers coupled with one or more non-volatile memory (NVM) arrays or other storage media such as rotating magnetic disks. Stored data may be subject to loss and/or corruption. For example, data may be lost, damaged, corrupted, etc., due to failure of memory cells, damage (e.g., physical damage), degradation, read/write disturbs, loss of data retention, loss of endurance, etc. Data storage devices may generally utilize one or more error correction codes (ECCs), error correction schemes, and/or error coding mechanisms to detect and/or correct errors in the data that is stored within the data storage devices (e.g., stored within the NVM arrays). For example, the data storage devices may generate codewords that encode data using an ECC. In another example, data storage devices may generate parity data that is used to protect data from loss (e.g., parity data that is used to recover, regenerate, recalculate, etc., data when data becomes inaccessible, corrupted, has errors, etc.).

Although parity data may be used to correct errors in data, using parity data may increase the amount of storage space used in a non-volatile memory to store the data (e.g., the protected data). Thus, it may be useful and/or more efficient to use codes that reduce the amount of parity data used to protect data stored on the data storage device. In addition, different codes may access a different amount of data on the data storage device to recover data. For example, if a block of data becomes corrupted, the data storage device may use all of the remaining data (e.g., the reaming blocks of data and parity data) stored on the data storage device to recover the data. This may result in an increased bandwidth usage for the data storage device. Thus, it may be useful and/or more efficient to use codes that reduce the amount of data that is accessed when recovering corrupted or inaccessible data.

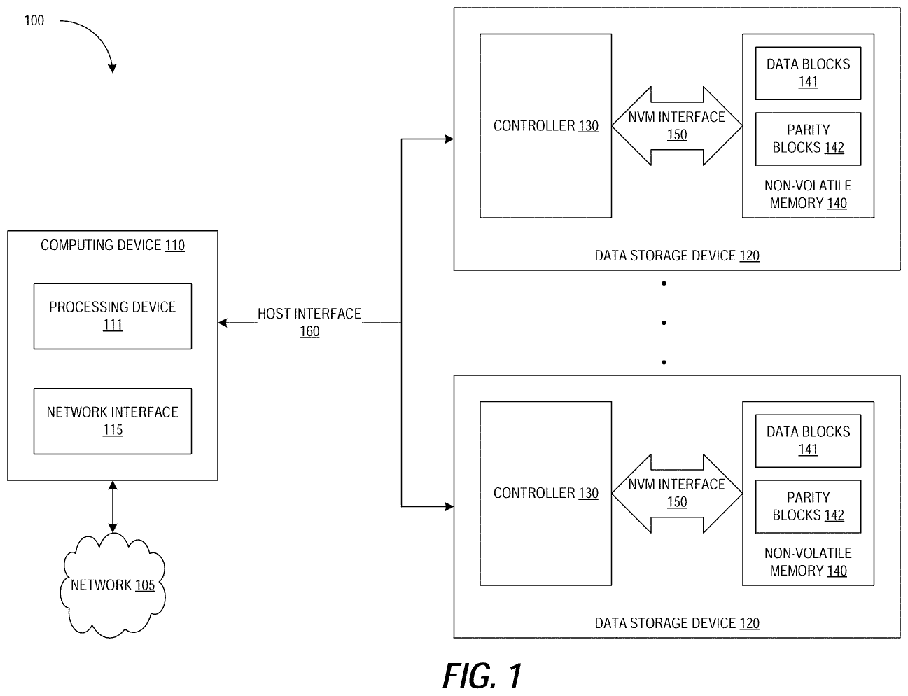

FIG. 1 is a diagram illustrating an example data storage system 100, in accordance with some embodiments of the present disclosure. The data storage system 100 includes a computing device 110 and one or more data storage devices 120. The computing device 110 may also be referred to as a host system. In one embodiment, the data storage device 120 may be part of the computing device 110 (e.g., may be located inside of a housing, chassis, case, etc., of the computing device 110). In another example, the data storage devices 120 may be separate from the computing device 110 (e.g., may be an external device that is coupled to the computing device 110 via a cable, such as a universal serial bus (USB) cable). In a further example, some of the data storage devices 120 may be part of the computing device 110 and other data storage devices 120 may be separate from the computing device 110. Examples of computing devices include, but are not limited to, phones (e.g., smart phones, cellular phones, etc.), cable set-top boxes, smart televisions (TVs), video game consoles, laptop computers, tablet computers, desktop computers, server computers, personal digital assistances, wearable devices (e.g., smart watches), media players, and/or other types of electronic devices.

The computing device 110 also includes a network interface 115. The network interface 115 may be hardware (e.g., a network interface card), software (e.g., drivers, applications, etc.), and/or firmware that allows the computing device 110 to communicate data with the network 105. The network interface card may be used to transmit and/or receive blocks of data, packets, messages, etc. In one embodiment, network 105 may include a public network (e.g., the Internet), a private network (e.g., a local area network (LAN)), a wide area network (WAN) such as the Internet, a wired network (e.g., Ethernet network), a wireless network (e.g., an 802.11 network or a Wi-Fi network), a cellular network (e.g., a Long Term Evolution (LTE) network), routers, hubs, switches, server computers, other types of computer networks, and/or a combination thereof. The computing device 110 may communicate (e.g., transmit and/or receive) data with other devices (e.g., other computing devices, other data storage devices, etc.) via the network 105.

Each data storage device 120 may incorporate access command scheduling and/or execution in accordance with embodiments, examples, and/or implementations disclosed herein. Each data storage device 120 may be any type of data storage device, drive, module, component, system, or the like. Furthermore, the terms “drive” and “data storage drive” may be used herein in certain contexts to refer to any type of data storage device, and may be used substantially interchangeably with the term “data storage device” herein in connection with various embodiments and/or in various contexts. As shown, Each data storage device 120 (e.g., hybrid hard drive, solid-state drive, any storage device utilizing solid-state memory, a hard disk drive, any storage device utilizing magnetic media/medium, etc.) includes a controller 130 (e.g., control circuitry, software, firmware, or a combination thereof) and a non-volatile memory 140.

The non-volatile memory (NVM) 140 may be configured for long-term storage of data and may retain data between power on/off cycles of the data storage device 120. The non-volatile memory 140 and/or portions of the non-volatile memory 140 may also be referred to as a storage medium. In some embodiments, the non-volatile memory 140 may include solid-state memory. Solid-state memory may comprise a wide variety of technologies, such as flash integrated circuits, Phase Change Memory (PC-RAM, PCM, or PRAM), Programmable Metallization Cell RAM (PMC-RAM or PMCm), Ovonic Unified Memory (OUM), Resistance RAM (RRAM), NAND memory (e.g., single-level cell (SLC) memory, multi-level cell (MLC) memory, triple level cell (TLC) memory, X4 or quad-level cell (QLC) memory, etc.), NOR memory, EEPROM, Ferroelectric Memory (FeRAM), magnetoresistive RAM (MRAM), or other discrete solid-state memory chips. In other embodiments, the non-volatile memory 140 may include magnetic media (including shingle magnetic recording), optical disks, floppy disks, electrically programmable read only memories (EPROM), electrically erasable programmable read only memories (EEPROM), etc. Non-volatile memory that uses magnetic media/medium may include one or more magnetic platters. Each platter may contain one or more regions of one or more tracks of data. The non-volatile memory 140 may include any combination of the one or more types of memories described here. The non-volatile memory 140 may be divided logically and/or physically into arrays, planes, blocks, pages, tracks, and sectors. While non-volatile memories are used as illustrative and teaching examples in this disclosure, those skilled in the art will recognize that various embodiments are applicable to volatile memories (e.g., Dynamic Random Access Memory (DRAM)) as well, as error correction codes are also used in those memories to protect data.

The controller 130 may include one or more processors, memory devices, data and/or power transmission channels/paths, boards, or the like. In some embodiments, the controller 130 may be implemented as one or more system-on-a-chip (SoC) modules, field-programmable gate array (FPGA) modules, application-specific integrated circuit (ASIC) modules, processing devices (e.g., processors), chips, or the like. In other embodiments, one or more components of the controller 130 may be mounted on a printed circuit board (PCB). The controller 130 may be configured to receive data commands from a storage interface (e.g., a device driver) residing on the computing device 110.

The controller 130 may communicate with the computing device 110 over a host interface 160, and may receive commands via the host interface 160. These commands may be referred to as data commands, data access commands, data storage access commands, etc. Data commands may specify a block address in the data storage device 120. Data may be accessed/transferred based on such data commands. For example, the controller 130 may receive data commands (from the computing device 110) and may execute such commands on/in the non-volatile memory 140 (e.g., in one or more arrays, pages, blocks, sectors, etc.). The data commands received from computing device 110 may include read data commands, write data commands, and erase data commands. The controller 130 may be coupled to the non-volatile memory (NVM) 140 via a NVM interface 150. In one embodiment, the NVM interface 150 may include a plurality of channels (e.g., one or more lines, pines, wires, traces, etc.) and each channel may be coupled to different portions of the non-volatile memory 140 (e.g., different NVM arrays, different flash arrays, etc.).

The controller 130 may execute the received data commands to read, write, and erase data from non-volatile memory 140, via the NVM interface 150. For example, the commands may include a read command (e.g. a data read command) to read a block of data from the non-volatile memory 140. The controller 130 may read the data from the page and may transmit the data to the computing device 110 via the host interface 160. In another example, the commands may include a write command (e.g., a data write command) to write data to a page in a non-volatile memory 140. In one embodiment, write commands may include program commands (e.g., a command to write the value “1” to a location the non-volatile memory 140) and erase commands (e.g., a command to write the value “0” to a location, a page, a block, etc., in the non-volatile memory array). The controller 130 may receive the data from the computing device 110 via the host interface 160 and may write the data to the page. The host interface 160 may include hardware (e.g., wires, pins, traces, connectors, etc.), software (e.g., drivers), firmware, or a combination thereof, that allows the processing device 111 and/or the computing device 110 to communicate data with the data storage device 120. Examples of a host interface may include a peripheral component interconnect express (PCIe) bus, a serial AT attachment (SATA) bus, a non-volatile memory express (NVMe) bus, etc.

The data storage device 120 may store data received from the computing device 110 such that the data storage device 120 acts as data storage for the computing device 110. To facilitate this function, the controller 130 may implement a logical interface. The logical interface may present to the computing device memory a set of logical addresses (e.g., sequential/contiguous addresses) where data may be stored. Internally, the controller 130 may map logical addresses to various physical memory addresses in the non-volatile memory arrays and/or other memory module(s). Mapping data indicating the mapping of logical addresses to physical memory addresses may be maintained in the data storage device. For example, mapping table data may be stored in non-volatile memory 140 in order to allow for recreation of mapping tables following a power cycle.

The controller 130 may encode data when storing the data on the non-volatile memory 140. The controller 130 may encode the data to protect the data from errors, loss, corruption, etc. The controller 130 may protect the data from errors, loss, corruption, etc., using various methods, techniques, functions, operations, actions, etc. In one embodiment, the controller 130 may protect the data by generating parity data (e.g., parity bits). The parity data may allow the controller 130 to determine whether there are errors in the data (e.g., errors due to corruption, damaged cells, damaged blocks, error while reading the data, etc.). The parity data (e.g., one or more parity bits) may be generated using various algorithms, techniques, functions, operations, etc. In another embodiment, the controller 130 may use an ECC to generate codewords. The codewords may also allow the controller 130 (e.g., the decoder 132) to correct or recover from errors in the codewords.

The controller 130 may also decode data that is stored on the non-volatile memory 140. In one embodiment, the controller 130 may decode codewords which encode the data that is stored on the non-volatile memory 140. In another embodiment, the controller 130 may perform error detection to determine the integrity of data retrieved from non-volatile memory 140 (e.g., to determine whether the data has errors). For example, the controller 130 may use parity data to check the data to determine whether there is an error in the data (e.g., whether one or more bits in the data are incorrect due to corruption, damage cells, damaged blocks, etc.).

As illustrated in FIG. 1, the non-volatile memory 140 includes data blocks 141 (e.g., each data block 141 is stored in a portion of the non-volatile memory 140). The data blocks 141 may be data that is used, accessed, etc., by users and/or other devices (e.g., other computing devices). For example, the data blocks 141 may be user data. Also as illustrated in FIG. 1, the non-volatile memory 140 includes parity blocks 142 (e.g., each parity block 142 is stored in a portion of the non-volatile memory 140). The parity blocks 142 may be parity data (e.g., one or more parity bits) that are used to recover, recalculate, regenerate, re-obtain, re-determine, etc., one or more data blocks 141 if the one or more data blocks 141 become corrupted, damaged, inaccessible, have errors, etc. The parity blocks 142 may include row parity blocks and diagonal parity blocks, as discussed in more detail below.

In one embodiment, the processing device 111 and/or controller 130 may obtain configuration data (e.g., may read the configuration data from a file, may receive the configuration data from the network interface 115, etc.). The configuration data may indicate a logical arrangement for a set of blocks that includes rows and columns of blocks, as discussed in more detail below. The configuration data may also indicate a number of row parity blocks in a set of row parity blocks and a number of diagonal parity blocks in a set of diagonal parity blocks. The processing device 111 and/or controller 130 may configure the data storage devices 120 based on the configuration data. For example, the processing device 111 and/or controller 130 may arrange the data blocks, diagonal parity blocks, and row parity blocks into rows and columns, as discussed in more detail below. The number of diagonal parity blocks in the set of diagonal parity blocks may less than the number of data blocks in a column. The number of diagonal parity blocks may also be less than the number of rows of data blocks. The number of row parity blocks in the set of parity blocks may be equal to the number of rows. The number of rows of data blocks may be equal to the number of columns of data blocks. Each diagonal party block may be generated, obtained, calculated, etc., based on data blocks in different rows and different columns, as discussed in more detail below. The total number of row parity blocks and diagonal parity blocks may be less than the number of blocks in two columns. The total amount of parity blocks stored in the data storage devices 120 (e.g., the repair overhead) may be less than the number of blocks in two columns of blocks, as discussed in more detail below. The processing device 111 and/or controller 130 may manage access to the data storage device 120. For example, the processing device 111 and/or controller 130 may execute commands to read, write, and/or access the non-volatile memory 140.

In one embodiment, the processing device 111 and/or controller 130 may determine that one or more data blocks of the set of data blocks has errors, is inaccessible, has become corrupted, etc. The processing device 111 and/or controller 130 may recover the one or more data blocks based on one or more of a subset of the set of data blocks, a subset the set of diagonal parity blocks, and a subset of the set of row parity blocks. The total number of blocks that are accessed, used, read, transmitted, etc., to recover a set of blocks (e.g., the repair bandwidth) may be less than the remaining number of blocks in the data storage devices 120, as discussed in more detail below.

Some embodiments of the present disclosure may use a diagonal code to reduce the repair bandwidth and/or repair overhead used by error correction codes, error correction schemes, error correction mechanisms, etc. The diagonal code may allow a data storage system to have a lower repair bandwidth when compared to other codes (such as SD codes) and may allow the data storage system to have a lower repair overhead when compared to other codes (such as butterfly codes). In addition, the diagonal code may allow the repair bandwidth (e.g., the number of blocks that are accessed to recover data) and/or the repair overhead (e.g., the number of that are used to store parity blocks) to be configurable. This allows a user to configure the data storage system with error correction capabilities, while maintaining a repair overhead and/or repair bandwidth that may be acceptable to the user.

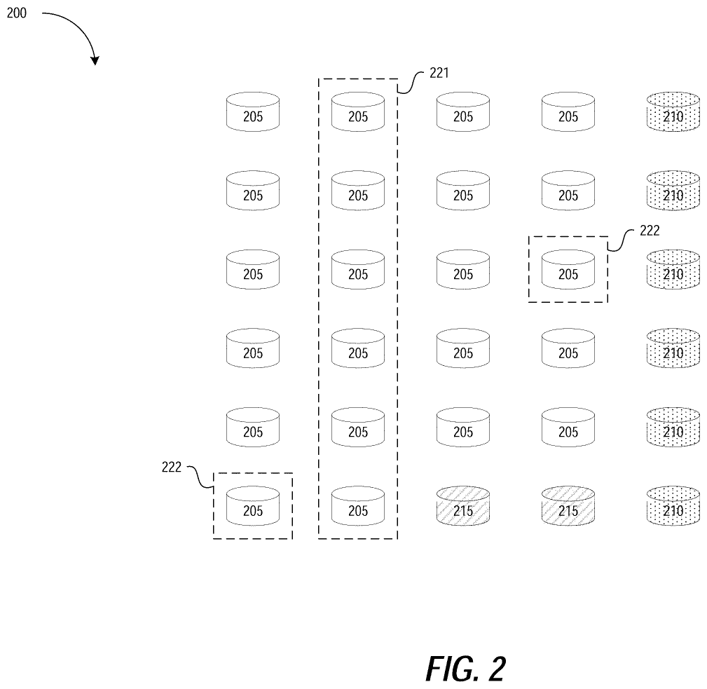

FIG. 2 is a diagram illustrating an example data storage system 200, in accordance with one or more embodiments of the present disclosure. As discussed above, the data storage system 200 may store data blocks 205 (e.g., blocks, pages, sectors, tracks, or portions of non-volatile memory that store data, such as user data). The data storage system 200 may use or utilize one or more error correction codes (ECCs), error correction schemes, and/or error coding mechanisms to detect and/or correct errors in one or more of the data blocks 205. For example, an ECC may be used to generate parity blocks (e.g., parity data) that may be used to detect and/or correct errors in one or more of the data blocks 205. The parity blocks may be used to detect and/or correct errors and/or failures that occur in the data storage system 200. For example, a parity block may be generated by exclusive ORing (XORing) multiple data blocks 205 together. In other embodiments, parity blocks may be generated, calculated, obtained, etc., using various other functions, operations, methods, algorithms, etc.

As illustrated in FIG. 2, the data storage system 200 includes blocks of data (e.g., a set of blocks) that include data blocks 205, row parity blocks 210, and global parity blocks 215. The blocks of data (e.g., data blocks 205, row parity blocks 210, and global parity blocks 215) may be logically arranged in rows and columns of blocks. For example, data blocks 205, row parity blocks 210, and global parity blocks 215 are logically arranged into six rows and five columns (e.g., five columns that each include six blocks or six rows that each include five blocks). The first and second columns (from the left) each include six data blocks 205. The third and fourth column (from the left) each include five data blocks 205 and one global parity block 215 at the bottom of the column. The fifth column (from the left) includes six row parity blocks 210. The blocks of data (e.g., data blocks 205, row parity blocks 210, and global parity blocks 215) may be located on one data storage device or may be located on multiple data storage devices. In one embodiment, the data storage system 200 may physically arrange the blocks according to the logical arrangement. For example, each column of blocks may be stored on a single data storage device. In another example, multiple columns of data may be stored on a single data storage device. In another embodiment, the physical arrangement of the blocks may be different from the logical arrangement of the blocks. For example, blocks from the same column may be stored on different data storage devices, different platters, different dies, etc.

In one embodiment, the data storage system 200 may use a sector-disk (SD) code to protect the data blocks 205 from loss, corruption, errors, etc. A SD code may be a type of error correction code, error correction scheme, error correction mechanism, etc., that may allow the data storage system 200 to recover, reconstruct, recalculate, regenerate, re-obtain, etc., data blocks 205 after errors occur, after the data blocks 205 are corrupted, damaged, etc. The SD code may use row parity blocks 210 and global parity blocks 215 to recover data blocks 205. In one embodiment, a row parity block may be parity data that is generated using the blocks in corresponding row. For example, the top-right parity block 210 may be generated, obtained, calculated, etc., using the four data blocks 205 that are in the first row of blocks. In another example, the top-right parity block 210 may be used to protect the data blocks 205 that are in the first row of blocks. In one embodiment, a global parity block may be parity data that is calculated using all of the data blocks 205 that are in the data storage system 200. For example, the global parity blocks 215 may be generated, obtained, calculated, etc., using the twenty-two data blocks 205 that stored in the data storage system 200.

As discussed above, the data storage system 200 may experience errors and/or failures which may cause one or more of the data blocks 205 to become unreadable, inaccessible, to have errors, etc. Also as discussed above, the data storage system 200 uses a sector-disk (SD) code (e.g., a SD error correction code, a SD coding scheme) to protect the data blocks 205. A SD code may be able to tolerate a certain number of errors in the data blocks 205. For example, the SD code may be able to recover the data blocks 205 if there are less than a threshold number of errors in the data blocks 205. As illustrated in FIG. 2, the SD code may allow the data storage system 200 to recover the data blocks 205 if there are errors in one column of data blocks 205 (e.g., a data storage drive or device becomes inoperable, damaged, corrupted, etc.), as illustrated by the rectangle 221. The SD code may also allow the data storage system to recover the data blocks if there are errors in two additional data blocks 205 (e.g., a block, page, sector, die, etc., of a data storage drive/device becomes inoperable, damaged, corrupted, etc.), as illustrated by the rectangles 222. In other embodiments, the maximum number of columns of data blocks 205 and the maximum number of additional data blocks (in addition to the columns of data blocks 205) that may be recovered using the SD code may be different. For example, a different type of SD code may allow a maximum of two columns of data blocks and three additional data blocks to be recovered.

As illustrated in FIG. 2, the SD code used by the data storage system 200 uses six row parity blocks 210 and two global parity blocks 215 to protect the data blocks 205 stored in the data storage system 200. Because each column of blocks includes six blocks of data, the SD code uses the 1.33 columns worth of blocks to store the parity blocks (e.g., the row parity blocks 210 and the global parity blocks 215) that are used to protect the data blocks 205. The number of parity blocks used by the SD code (or other error correction code, error correction mechanism, error correction scheme, etc.) may be referred to as the repair overhead. Thus, the SD code (illustrated in FIG. 2) may have a repair overhead of 1.33 because the number of parity blocks used by the SD code may be the same as the number of blocks in 1.33 columns of the data storage system 200. Generally, a lower repair overhead may be more desirable and/or efficient. For example, a lower repair overhead may allow a data storage system to use less space (e.g., few blocks, fewer pages, etc.) to store the parity data that may be used to recover data blocks that have errors, become corrupted/damaged, etc. Thus, a lower repair overhead may indicate that the data storage system uses less storage overhead (e.g., less storage space) to store the parity blocks.

If the data storage system 200 recovers the data blocks 205 in a column (e.g., in the rectangle 221) using a SD code, the data storage system 200 may access or read the all of the remaining data blocks 205 (e.g., sixteen data blocks 205), the global parity blocks 215 and the row parity blocks 210. For example, the data storage system 200 may read, access, etc., a total of twenty four blocks (e.g., sixteen data blocks 205, two global parity blocks 215 and six row parity blocks 210) in order to recover the data blocks in the second column (indicated by the rectangle 221). Thus, when the data storage system uses SD codes to protect the data blocks 205, the data storage system 200 may access all of the remaining blocks that have not failed or do not have errors (e.g., data blocks 205, global parity blocks 215, and row parity blocks 210) to reconstruct, recover, etc., the data blocks 205 in the second column. The number of blocks that are used by the data storage system 200 to recover data blocks 205 may be referred to as the repair bandwidth. Thus, the SD code (illustrated in FIG. 2) may have a repair bandwidth of 1 because all of the remaining blocks in the data storage system 200 (e.g., twenty-four blocks out of the twenty-four remaining blocks, which is 24/24 which equals 1) are used to recover the data blocks 305 in the second column. Generally, a lower repair bandwidth may be more desirable and/or efficient. For example, a lower repair bandwidth may indicate that a data storage system has to read, access, transmit, etc., few blocks to recover data blocks that have errors, become corrupted/damaged, etc. For example, a repair bandwidth of 1 may be less desirable and/or efficient because a repair bandwidth of less than 1 indicates that the data storage system 200 will access, read, etc., fewer than all of the remaining blocks in the system to recover a column of data blocks 305.

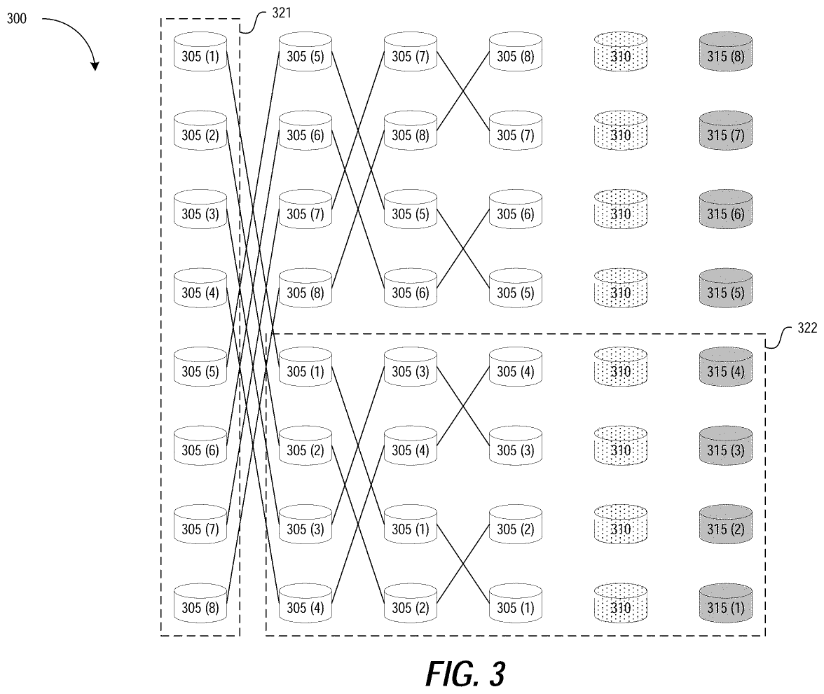

FIG. 3 is a diagram illustrating an example data storage system 300, in accordance with one or more embodiments of the present disclosure. As discussed above, the data storage system 300 may store data blocks 305 (e.g., blocks, pages, sectors, tracks, or portions of non-volatile memory that store data, such as user data). The data storage system 300 may use or utilize one or more error correction codes (ECCs), error correction schemes, and/or error coding mechanisms to detect and/or correct errors in one or more of the data blocks 305. For example, the data storage system 300 may use parity blocks to detect and/or correct errors in one or more of the data blocks 305. The parity blocks may be generated, calculated, obtained, etc., using various other functions, operations, methods, algorithms, etc.

As illustrated in FIG. 3, the data storage system 300 includes blocks of data (e.g., a set of blocks) that include data blocks 305, row parity blocks 310, and butterfly parity blocks 315. The blocks of data (e.g., data blocks 305, row parity blocks 310, and butterfly parity blocks 315) may be logically arranged in rows and columns of blocks. For example, data blocks 305, row parity blocks 310, and butterfly parity blocks 315 are logically arranged into eights rows and six columns (e.g., six columns that each include eight blocks or eight rows that each include six blocks). The first, second, third, and fourth columns (from the left) each include eight data blocks 305. The fifth column (from the left) includes eight row parity blocks 310. The sixth column (from the left) includes eight butterfly parity blocks 315. The blocks of data (e.g., data blocks 305, row parity blocks 310, and butterfly parity blocks 315) may be located on one data storage device or may be located on multiple data storage devices. In one embodiment, the data storage system 300 may physically arrange the data according to the logical arrangement. In another embodiment, the physical arrangement of the blocks may be different from the logical arrangement of the blocks.

In one embodiment, the data storage system 300 may use a butterfly code to protect the data blocks 305 from loss, corruption, errors, etc. A butterfly code may be a type of error correction code, error correction scheme, error correction mechanism, etc., that may allow the data storage system 300 to recover, reconstruct, recalculate, regenerate, re-obtain, etc., data blocks 305 after errors occur, after the data blocks 305 are corrupted, damaged, etc. The butterfly code may use row parity blocks 310 and butterfly parity blocks 315 to recover data blocks 305. In one embodiment, a row parity block may be parity data that is generated using the blocks in a corresponding row. For example, the top-right parity block 310 may be generated, obtained, calculated, etc., using the four data blocks 305 that are in the first row of blocks. In another example, the top-right parity block 310 may be used to protect the data blocks 305 that are in the first row of blocks. In one embodiment, a butterfly parity block may be parity data that is calculated using one data block 305 from different columns and rows. For example, the butterfly parity blocks 315 (8) may be generated, obtained, calculated, etc., using the data blocks labelled 305 (8) (e.g., the last data block 305 from the top in the first column, the fourth data block 305 from the top in the second column, the second data block 305 from the top in the third column, and the first data block 305 from the top in the fourth column). The data blocks labelled (X) may referred to as a stripe of data or data stripe. A data stripe may be blocks of data that may be written across the columns of data blocks (i.e., written across the four leftmost columns) in different rows. For example, the four data blocks labeled 305 (1) may form a first data stripe, the four data blocks labeled 305 (2) may form a second data stripe, the four data blocks labeled 305 (3) may form a third data stripe, and the four data blocks labeled 305 (4) may form a fourth data stripe, etc. The butterfly parity blocks 315 may be generated, obtained, calculated, etc., using the data blocks 305 in a stripe, as discussed above.

As discussed above, the data storage system 300 may experience errors and/or failures which may cause one or more of the data blocks 305 to become unreadable, inaccessible, to have errors, etc. Also as discussed above, the data storage system 300 uses a butterfly code (e.g., a butterfly error correction code, a butterfly coding scheme) to protect the data blocks 305. A butterfly code may be able to tolerate a certain number of errors in the data blocks 305. For example, the butterfly code may be able to recover a column of data blocks 305 that becomes corrupted, lost, has errors, etc. As illustrated in FIG. 3, the butterfly code may allow the data storage system 300 to recover the data blocks 305 if there are errors in one column of data blocks 305 (e.g., a data storage drive or device becomes inoperable, damaged, corrupted, etc.), as illustrated by the rectangle 221.

As illustrated in FIG. 3, the butterfly code used by the data storage system 300 uses eight row parity blocks 310 and eight butterfly parity blocks 315 to protect the data blocks 305 stored in the data storage system 300. Because each column of blocks includes eight blocks of data, the butterfly code uses the 2 columns worth of blocks to store the parity blocks (e.g., the row parity blocks 310 and the butterfly parity blocks 315) that are used to protect the data blocks 305. The number of parity blocks used by the butterfly code (or other error correction code, error correction mechanism, error correction scheme, etc.) may be referred to as the repair overhead. Thus, the butterfly code (illustrated in FIG. 3) may have a repair overhead of 2 because the number of parity blocks used by the butterfly code may be the same as the number of blocks in 2 columns of the data storage system 300. As discussed above, a lower repair overhead may be more desirable and/or efficient. A lower repair overhead may indicate that the data storage system uses less storage overhead (e.g., less storage space) to store the parity blocks. Thus, the butterfly code illustrated in FIG. 3 uses more data (e.g., more parity blocks) to recover data blocks than the SD code illustrated in FIG. 2.

As illustrated in FIG. 3, the blocks 305 in the first column (from the left) may be lost, corrupted, or may have errors. If the data storage system 300 recovers the data blocks 305 in the first column (e.g., in the rectangle 321) using a butterfly code, the data storage system 300 may access or read blocks that are in the rectangle 322. For example, the data storage system 300 may read, access, etc., a total of twenty blocks (e.g., twelve data blocks 305, four butterfly parity blocks 315 and four row parity blocks 310) in order to recover the data blocks in the first column (indicated by the rectangle 321). Thus, when the data storage system uses butterfly codes to protect the data blocks 305, the data storage system 300 may access as little as half of the remaining blocks that have not failed or do not have errors (e.g., twenty out of the forty data blocks 305, butterfly parity blocks 315, and row parity blocks 310) to reconstruct, recover, etc., the data blocks 305 in the first column.

As discussed above, the number of blocks that are used by the data storage system 300 to recover data blocks 305 may be referred to as the repair bandwidth. The data storage system 300 may use a different number of blocks to recover different columns of data blocks 305. For example, the data storage system 300 may access twenty blocks of data to recover the data blocks in the first column, and may access twenty-six blocks of data to recover the data blocks in each of the second, third, and fourth column. Thus, the average repair bandwidth for the butterfly code (illustrated in FIG. 3) may be calculated as (((26+26+26+20)/4)/36) which is 0.68. As discussed above, a lower repair bandwidth may generally be more desirable and/or efficient. For example, a repair bandwidth of less than 1 may be more desirable and/or efficient because a repair bandwidth of less than 1 indicates that the data storage system 300 will access, read, etc., fewer than all of the remaining blocks in the system to recover a column of data blocks 305. This may indicate that the data storage system 300 (which uses the butterfly code) is able to recover data blocks more efficiently when compared with the data storage system 200 (which uses the SD code).

In addition, the number of rows in the logical arrangement of blocks may increase exponentially with the number of columns of data blocks 305 when the data storage system 300 uses a butterfly code to protect the data blocks 305. For example, if there are four columns of data blocks 305, then the logical arrangement of blocks includes eight rows of blocks, as illustrated in FIG. 2. In another example, if there are eight columns of data blocks 305, then the logical arrangement of blocks would include one-hundred and twenty-eight rows of blocks. Generally, a data storage system using a butterfly code may include c columns and 2\hat{ }(c−1) rows of data blocks. The larger number of rows (when compared to the SD code illustrated in FIG. 2) may be due in part to the use of the butterfly parity blocks. Thus, a data storage system that uses a butterfly code may use a larger number of rows (e.g., an exponentially larger number of rows) to generate the butterfly parity blocks that may be used to protect data blocks.

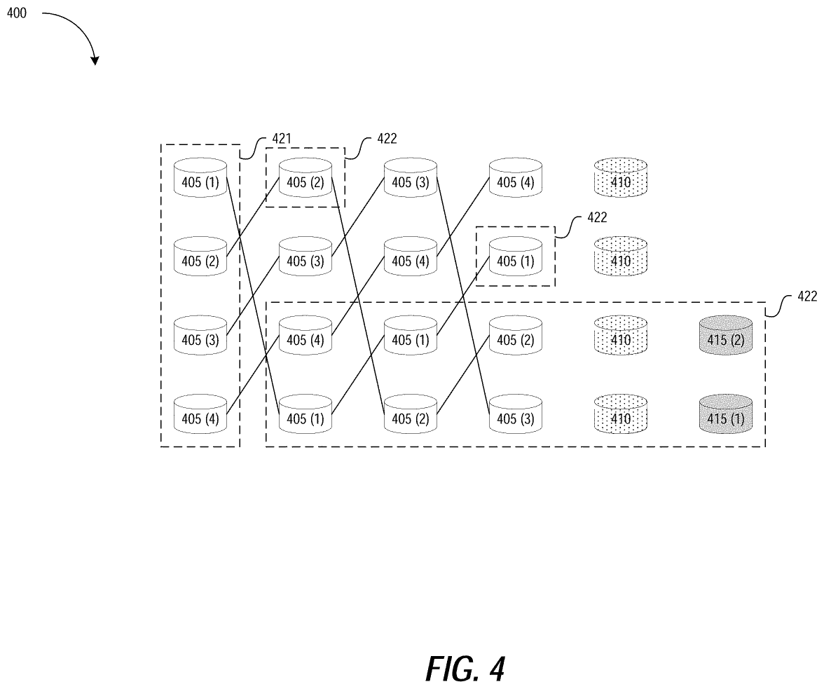

FIG. 4 is a diagram illustrating an example data storage system 400, in accordance with one or more embodiments of the present disclosure. As discussed above, the data storage system 400 may store data blocks 405 (e.g., blocks, pages, sectors, tracks, or portions of non-volatile memory that store data, such as user data). The data storage system 400 may use or utilize one or more error correction codes (ECCs), error correction schemes, and/or error coding mechanisms to detect and/or correct errors in one or more of the data blocks 405. For example, the data storage system 400 may use parity blocks to detect and/or correct errors in one or more of the data blocks 405. The parity blocks may be generated, calculated, obtained, etc., using various other functions, operations, methods, algorithms, etc.

As illustrated in FIG. 4, the data storage system 400 includes blocks of data (e.g., a set of blocks) that include data blocks 405, row parity blocks 410, and diagonal parity blocks 415. The blocks of data (e.g., data blocks 405, row parity blocks 410, and diagonal parity blocks 415) may be logically arranged in rows and columns of blocks. For example, data blocks 405, row parity blocks 410, and diagonal parity blocks 415 are logically arranged into five and a half columns and four rows. The first, second, third, and fourth columns (from the left) each include four data blocks 405. The fifth column (from the left) includes four row parity blocks 410. The sixth column (from the left), which may be referred to as a half column, includes two diagonal parity blocks 415. The blocks of data (e.g., data blocks 405, row parity blocks 410, and diagonal parity blocks 415) may be located on one data storage device or may be located on multiple data storage devices. In one embodiment, the data storage system 400 may physically arrange the data according to the logical arrangement. In another embodiment, the physical arrangement of the blocks may be different from the logical arrangement of the blocks.

In one embodiment, the data storage system 400 may use a diagonal code to protect the data blocks 405 from loss, corruption, errors, etc. A diagonal code may be a type of error correction code, error correction scheme, error correction mechanism, etc., that may allow the data storage system 400 to recover, reconstruct, recalculate, regenerate, re-obtain, etc., data blocks 405 after errors occur, after the data blocks 405 are corrupted, damaged, etc. The diagonal code may use row parity blocks 410 and diagonal parity blocks 415 to recover data blocks 405. In one embodiment, a row parity block may be parity data that is generated using the blocks in corresponding row. For example, the top-right parity block 410 may be generated, obtained, calculated, etc., using the four data blocks 405 that are in the first row of blocks. In another example, the top-right parity block 410 may be used to protect the data blocks 405 that are in the first row of blocks. In one embodiment, a diagonal parity block may be parity data that is calculated using data blocks 405 from different columns and rows. For example, the diagonal parity blocks 415 (1) may be generated, obtained, calculated, etc., using the data blocks labelled 405 (1) (e.g., the first data block 405 from the top in the first column, the fourth data block 405 from the top in the second column, the third data block 405 from the top in the third column, and the second data block 405 from the top in the fourth column). The data blocks labelled (X) may referred to as a stripe of data or data stripe. A data stripe may be blocks of data that may be written across the columns of data blocks (i.e., written across the four leftmost columns). For example, the four data blocks labeled 405 (1) may form a first data stripe, the four data blocks labeled 405 (2) may form a second data stripe, the four data blocks labeled 405 (3) may form a third data stripe, and the four data blocks labeled 405 (4) may form a fourth data stripe.

In other embodiments, the number of rows and columns of data blocks 405, row parity blocks 410, and diagonal parity blocks 415 may be different. For example, there may be eight columns of data blocks each column with eight data blocks 405, one column of row parity blocks 410 with eight row parity blocks 401, and four diagonal parity blocks 415. The data blocks 405 may be arranged such that the data blocks 405 from the different stripes (e.g., the first, second, third, and fourth data stripes labeled (1), (2), (3), and (4) respectively) are in an order in the first column (e.g., a leftmost column). For a subsequent column (e.g., the next column) the order of the stripes of the data blocks 405 may be changed. For stripe of the topmost data block 405 may be moved to the bottom of the subsequent column and the stripes for the other data blocks 405 may be shifted upwards to create a new order of stripes of data blocks 405 in the subsequent column. Each subsequent column may arrange the stripes of the data blocks 405 in a new order by moving the strip of the topmost data bock 405 of the previous column to the bottom and shifting the other stripes of the data blocks 405 upwards. The diagonal parity blocks 415 may be generated, obtained, calculated, etc., using the data blocks 405 in a stripe.

As discussed above, the data storage system 400 may experience errors and/or failures which may cause one or more of the data blocks 405 to become unreadable, inaccessible, to have errors, etc. Also as discussed above, the data storage system 400 uses a diagonal code (e.g., a diagonal error correction code, a diagonal coding scheme) to protect the data blocks 405. A diagonal code may be able to tolerate a certain number of errors in the data blocks 405. For example, the diagonal code may be able to recover a column of data blocks 405 that becomes corrupted, lost, has errors, etc. As illustrated in FIG. 4, the diagonal code may allow the data storage system 400 to recover the data blocks 405 if there are errors in one column of data blocks 405 (e.g., a data storage drive or device becomes inoperable, damaged, corrupted, etc.), as illustrated by the rectangle 221.

As illustrated in FIG. 4, the diagonal code used by the data storage system 400 uses four row parity blocks 410 and two diagonal parity blocks 415 to protect the data blocks 405 stored in the data storage system 400. Because each column of blocks includes four blocks of data, the diagonal code uses the 1.5 columns worth of blocks to store the parity blocks (e.g., the row parity blocks 410 and the diagonal parity blocks 415) that are used to protect the data blocks 405. The number of parity blocks used by the diagonal code (or other error correction code, error correction mechanism, error correction scheme, etc.) may be referred to as the repair overhead. Thus, the diagonal code (illustrated in FIG. 4) may have a repair overhead of 1.5 because the number of parity blocks used by the diagonal code may be the same as the number of blocks in 1.5 columns of the data storage system 400 (e.g., six parity blocks are used). As discussed above, a lower repair overhead may be more desirable and/or efficient. A lower repair overhead may indicate that the data storage system uses less storage overhead (e.g., less storage space) to store the parity blocks. Thus, the diagonal code illustrated in FIG. 4 uses less storage overhead or storage space than the SD code illustrated in FIG. 2, to recover data blocks.

As illustrated in FIG. 4, the data storage system 400 includes two diagonal parity blocks 415. The first diagonal parity block (labeled 415 (1)) may be used to recover the data blocks labeled 405 (1) and the second diagonal parity block (labeled 415 (2)) may be used to recover the data blocks labeled 405 (2). In the embodiment illustrated in FIG. 4, diagonal parity blocks may not be calculated or the data blocks labelled 405 (3). In other embodiments a different number of diagonal parity blocks 415 may be used in the data storage system 400 and/or in the diagonal code. For example, the data storage system 400 may use three diagonal parity blocks for the data blocks labeled 405 (1), 405 (2), and 405 (3). In some embodiments, the number of diagonal parity blocks 415 may be less than the number of blocks in column. For example, in the logical arrangement of blocks illustrated in FIG. 4, there may be one, two, or three diagonal parity blocks. Because the diagonal code may use less than the number of blocks in a column to store diagonal parity blocks, the diagonal code may have a repair overhead that is less than two. For example, the number of blocks used for row parity blocks and diagonal parity blocks is less than the number of blocks in two columns of blocks. The diagonal code illustrated in FIG. 4 has a repair overhead of 1.5 (e.g., the number of row parity blocks and diagonal parity blocks is equal to the number of blocks in 1.5 columns of the data storage system 400). By using a lower repair overhead, the data storage system 400 and/or the diagonal code may use less overhead (e.g., less storage space, less blocks of data, etc.) to store the parity blocks (e.g., the row parity blocks 410 and the diagonal parity blocks 415).

As illustrated in FIG. 4, the data blocks 405 in the first column (from the left) may be lost, corrupted, or may have errors. If the data storage system 400 recovers the data blocks 405 in the first column (e.g., in the rectangle 421) using a diagonal code, the data storage system 400 may access or read blocks that are in the rectangles 422. For example, the data storage system 400 may read, access, etc., a total of twelve blocks (e.g., eight data blocks 405, two diagonal parity blocks 415, and two row parity blocks 410) in order to recover the data blocks in the first column (indicated by the rectangle 321).

As discussed above, the number of blocks that are used by the data storage system 400 to recover data blocks 405 may be referred to as the repair bandwidth. When a column of data blocks becomes inaccessible, becomes corrupted, has errors, etc., the data storage system 400 may use twelve blocks out of the remaining eighteen blocks to recover the column of data blocks. For example, if the each of the first column, second column, third column, or fourth column of data blocks becomes inaccessible, the data storage system 400 may access twelve blocks of data (e.g., twelve total of data blocks 405, row parity blocks 410, and diagonal parity blocks 415) to recover the column of data blocks 405. Thus, the repair bandwidth for the diagonal code (illustrated in FIG. 4) may be calculated as (12/18) which is 0.66. As discussed above, a lower repair bandwidth may be more desirable and/or efficient. For example, a lower repair bandwidth may allow a data storage system to use access, read, transmit, etc., fewer blocks when recovering data blocks that have errors, become corrupted/damaged, etc. The repair bandwidth for the diagonal code is less than the repair bandwidth of the SD code (e.g., 1) and is close to the repair bandwidth of the butterfly code (e.g., 0.68).

In one embodiment, the repair bandwidth for the diagonal code used by the data storage system 400 may be constant or the same regardless of which column of data blocks 405 becomes inaccessible, corrupted, has errors, etc. As discussed above, the data storage system 400 may access twelve blocks of data regardless of whether the first, second, third or fourth column of data has become inaccessible. This may allow a more predictable and/or constant usage of the data storage system 400 when recovering data blocks, when compared with other codes such as butterfly codes. For example, if the data storage system 400 determines that data blocks have become inaccessible, the data storage system 400 may be able to more accurately predict the bandwidth (e.g., the amount of data that should be accessed, read, transmitted, etc.) to recover the inaccessible data blocks.

In addition, the number of rows of data blocks 405 is equal to the number of columns of data blocks 405 in the logical arrangement of blocks. This may be similar to the numbers and rows of data blocks used by the SD code illustrated in FIG. 2. This may also less than the number of rows and columns of data blocks used by the butterfly code illustrated in FIG. 3 (where the number of rows increases exponentially with the number of columns of data blocks.

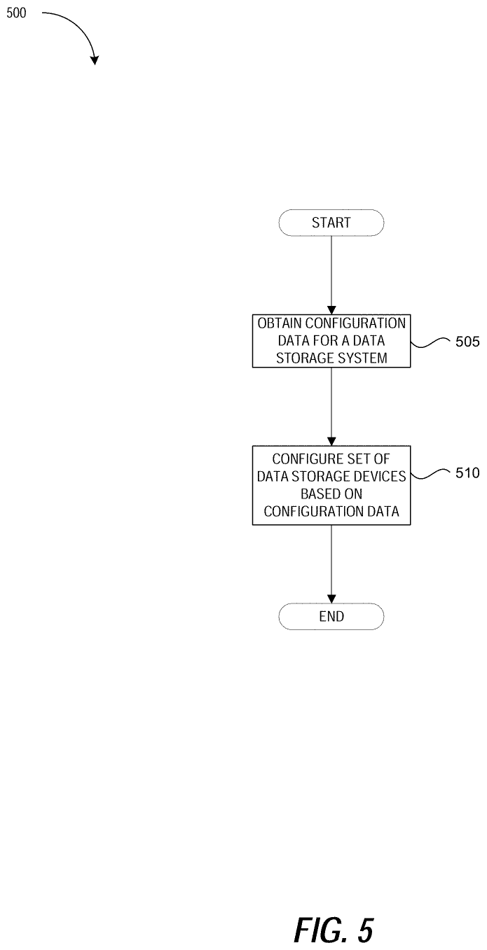

FIG. 5 is a flowchart illustrating an example a method 500 for configuring a data storage system (e.g., data storage system 400 illustrated in FIG. 4), in accordance with one or more embodiments of the present disclosure. The method 500 may be performed by a processing device (e.g., a processor, a central processing unit (CPU), a controller, an application-specific integrated circuit (ASIC), a field programmable gate array (FPGA), etc.), etc. For example, the method 500 may be performed by a processing device of a computing device. In another example, the method 500 may be performed by a controller of a data storage device. The controller and/or processing device may be processing logic that includes hardware (e.g., circuitry, dedicated logic, programmable logic, microcode, etc.), software (e.g., instructions run on a processor to perform hardware simulation), firmware, or a combination thereof.

The method 500 starts at block 505 where the method 500 may obtain configuration data for the data storage system. For example, the method 500 may receive the configuration data from another device (e.g., another computing device) via a network interface. In another example, the method 500 may receive the configuration data via an interface, such as a graphical user interface, a command line interface, etc. In a further example, the method 500 may obtain the configuration data from a configuration file, settings, parameters, etc., that may be stored in the data storage system or in another data storage device. The data storage system may use a diagonal code, as illustrated in FIG. 4. Thus, the data storage system may include data blocks, row parity blocks, and diagonal parity blocks, as illustrated in FIG. 4.

In one embodiment, the configuration data may indicate a logical arrangement of blocks for the data storage system. For example, the configuration data may indicate how many rows are in the logical arrangement, how may columns are in the logical arrangement, how many blocks are in each row, how many blocks are in each column, etc. The configuration data may also indicate how many row parity blocks are in the data storage system. For example, the configuration data may indicate the number of row parity blocks in a column. The configuration data may also indicate how many diagonal parity blocks are in the data storage system. For example, the configuration data may indicate how many diagonal parity blocks are in a column. The configuration data may also indicate which data blocks are used to generate, obtain, calculate, determine, etc., the row parity blocks and/or diagonal parity blocks. For example, configuration data may indicate that each row of data blocks is used to determine a row parity block. In another example, the configuration data may indicate which blocks from different rows and columns are used to generate a diagonal parity block.

At block 510, the method 500 may configure a set of data storage devices (e.g., one or more data storage device) of the data storage system. For example, the method 500 may store the data blocks based on the logical arrangement indicated in the configuration data. In another example, the method 500 may generate the row parity blocks and diagonal parity blocks based on the logical arrangement indicated in the configuration data. For example, the method 500 may generate a diagonal parity blocks based on the configuration data, which indicates which blocks from different rows and columns are used to generate the diagonal parity block.

In some embodiments, the configuration data allows the repair bandwidth (e.g., the number of blocks that are accessed to recover data) and/or the repair overhead (e.g., the number of that are used to store parity blocks) to be configurable. For example, a user may change the configuration data by changing the number of diagonal parity blocks that are used by the data storage system. This may change the repair bandwidths and/or the repair overhead of the data storage system and the diagonal code. The diagonal code used by the data storage system may be configurable such that the repair bandwidth is less than 1 and repair overhead is less than 2, as discussed above. This allows the user to configure the data storage system with error correction capabilities, while maintaining a repair overhead and/or repair bandwidth that may be acceptable to the user.

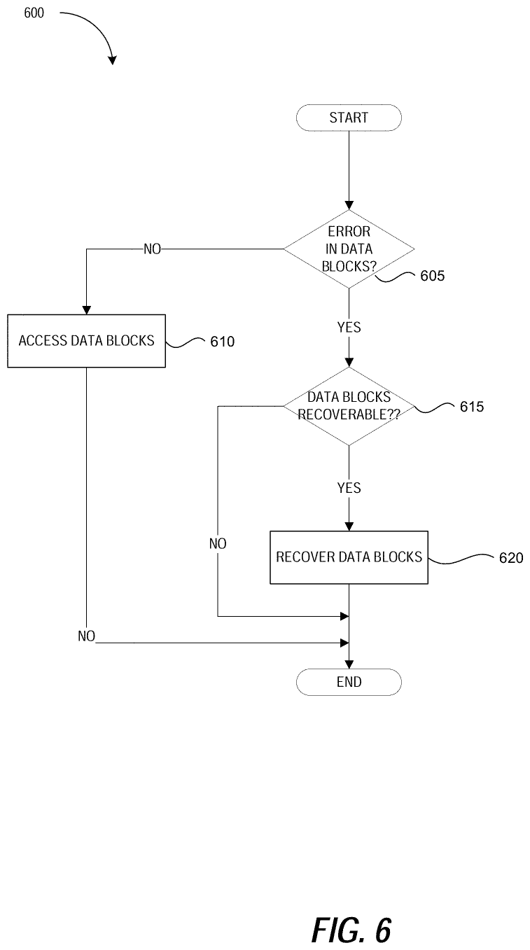

FIG. 6 is a flowchart illustrating an example a method 600 for recovering data blocks in a data storage system (e.g., data blocks 405 in data storage system 400 illustrated in FIG. 4), in accordance with one or more embodiments of the present disclosure. The method 600 may be performed by a processing device (e.g., a processor, a central processing unit (CPU), a controller, an application-specific integrated circuit (ASIC), a field programmable gate array (FPGA), etc.), etc. For example, the method 600 may be performed by a processing device of a computing device. In another example, the method 600 may be performed by a controller of a data storage device. The controller and/or processing device may be processing logic that includes hardware (e.g., circuitry, dedicated logic, programmable logic, microcode, etc.), software (e.g., instructions run on a processor to perform hardware simulation), firmware, or a combination thereof. As discussed above, the data storage system may use a diagonal code, as illustrated in FIG. 4. Thus, the data storage system may include data blocks, row parity blocks, and diagonal parity blocks, as illustrated in FIG. 4.

The method 600 starts at block 605 where the method 600 determines whether there are errors in one or more data blocks. For example, when the data storage devices tries to access one or more data blocks, the method 600 may determine whether there are error in the data blocks. If there are no errors in the data blocks, the method 600 may access the data blocks at block 610. For example, the method 600 may read the one or more data blocks. If there is an error in the one or more data blocks, the method 600 may determine whether the one or more data blocks are recoverable at block 615. For example, the method 600 may determine whether there are errors in less than a threshold number of data blocks (e.g., whether less than a single column of data blocks has errors). If the one or more data blocks are not recoverable, the method 600 ends. For example, if there are too many columns of data blocks with errors (e.g., more than a single column of data blocks has errors), the method 600 may end because the method 600 may be unable to recover the data blocks using the diagonal code. If the one or more data blocks are recoverable, the method 600 may recover the one or more data blocks at block 620. For example, the method 600 may recover the one or more data blocks using other data blocks, row parity blocks, and/or diagonal parity blocks, as discussed above. The total number of blocks that are accessed or used to recover the one or more blocks may be less than the number of blocks remaining in the data storage system (e.g., the repair bandwidth may be less than 1), as discussed above.

Some embodiments of the present disclosure may be used to reduce the repair bandwidth and/or repair overhead used by error correction codes, error correction schemes, error correction mechanisms, etc. For example, some embodiments may use a diagonal code, a diagonal coding scheme, etc., to protect data blocks from loss. The diagonal code may allow a data storage system to have a lower repair bandwidth when compared to other codes (such as SD codes) and may allow the data storage system to have a lower repair overhead when compared to other codes (such as butterfly codes). In addition, the diagonal code may allow the repair bandwidth (e.g., the number of blocks that are accessed to recover data) and/or the repair overhead (e.g., the number of that are used to store parity blocks) to be configurable. This allows a user to configure the data storage system with error correction capabilities, while maintaining a repair overhead and/or repair bandwidth that may be acceptable to the user.

### General Comments

Those skilled in the art will appreciate that in some embodiments, other types of distributed data storage systems may be implemented while remaining within the scope of the present disclosure. In addition, the actual steps taken in the processes discussed herein may differ from those described or shown in the figures. Depending on the embodiment, certain of the steps described above may be removed, others may be added.

While certain embodiments have been described, these embodiments have been presented by way of example only, and are not intended to limit the scope of protection. Indeed, the novel methods and systems described herein may be embodied in a variety of other forms. Furthermore, various omissions, substitutions and changes in the form of the methods and systems described herein may be made. The accompanying claims and their equivalents are intended to cover such forms or modifications as would fall within the scope and spirit of the protection. For example, the various components illustrated in the figures may be implemented as software and/or firmware on a processor, ASIC/FPGA, or dedicated hardware. Also, the features and attributes of the specific embodiments disclosed above may be combined in different ways to form additional embodiments, all of which fall within the scope of the present disclosure. Although the present disclosure provides certain preferred embodiments and applications, other embodiments that are apparent to those of ordinary skill in the art, including embodiments which do not provide all of the features and advantages set forth herein, are also within the scope of this disclosure. Accordingly, the scope of the present disclosure is intended to be defined only by reference to the appended claims.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this disclosure, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this disclosure and the appended claims should generally be construed to mean “one or more” unless specified otherwise or clear from context to be directed to a singular form. Moreover, use of the term “an embodiment” or “one embodiment” or “an implementation” or “one implementation” throughout is not intended to mean the same embodiment or implementation unless described as such. Furthermore, the terms “first,” “second,” “third,” “fourth,” etc., as used herein are meant as labels to distinguish among different elements and may not necessarily have an ordinal meaning according to their numerical designation.

All of the processes described above may be embodied in, and fully automated via, software code modules executed by one or more general purpose or special purpose computers or processors. The code modules may be stored on any type of computer-readable medium or other computer storage device or collection of storage devices. Some or all of the methods may alternatively be embodied in specialized computer hardware.

What is claimed is:

1. An apparatus, comprising:
a set of storage devices comprising a set of blocks logically arranged in rows and columns, wherein the set of blocks comprises
a set of data blocks;
a set of row parity blocks; and
a set of diagonal parity blocks, wherein a first number of diagonal parity blocks in the set of diagonal parity blocks is less than a second number of data blocks in a column; and
a processing device coupled to the set of storage devices, the processing device configured to manage access to the set of storage devices.

2. The apparatus of claim 1, wherein each row parity block of the set of row parity blocks is obtained based on a row of data blocks.

3. The apparatus of claim 1, wherein a first number of row parity blocks in the set of row parity blocks is equal to a second number of rows.

4. The apparatus of claim 1, wherein a first number of rows of data blocks is equal to a second number of columns of data blocks.

5. The apparatus of claim 1, wherein each diagonal parity block of the set of diagonal parity blocks is obtained based on data blocks in different rows and different columns.

6. The apparatus of claim 1, wherein the first number of diagonal parity blocks in the set of diagonal parity blocks is less than a second number of rows.

7. The apparatus of claim 1, wherein a total number of row parity blocks and diagonal parity blocks is less than a first number of data blocks in two columns.

8. The apparatus of claim 1, wherein the processing device is further configured to:
obtain configuration data indicating one or more of:
a logical arrangement of the set of blocks;
a number of row parity blocks; and
a number of diagonal parity blocks; and
configure the set of storage devices and set of storage blocks based on the configuration data.

9. The apparatus of claim 1, wherein the processing device is further configured to:
determine whether one or more data blocks of the set of data blocks comprises one or more errors; and
recovering the one or more data blocks based on one or more of:
a first subset of the set of data blocks;
a second subset the set of diagonal parity blocks; and
a third subset of the set of row parity blocks.

10. The apparatus of claim 9, wherein a total number of blocks used to recover the one or more data blocks is less than a remaining number of blocks.

11. A method comprising:
obtaining a configuration data, wherein the configuration data indicates:
a logical arrangement for a set of blocks, wherein the logical arrangement comprises rows and columns of blocks;
a number of row parity blocks in a set of row parity blocks; and
a number of diagonal parity blocks in a set of diagonal parity blocks; and
configuring a set of storage devices based on the configuration data, wherein a first number of diagonal parity blocks in the set of diagonal parity blocks is less than a second number of data blocks in a column.

12. The method of claim 11, wherein each row parity block of the set of row parity blocks is obtained based on a row of data blocks.

13. The method of claim 11, wherein a first number of row parity blocks in the set of row parity blocks is equal to a second number of rows.

14. The method of claim 11, wherein a first number of rows of data blocks is equal to a second number of columns of data blocks.

15. The method of claim 11, wherein each diagonal parity block of the set of diagonal parity blocks is obtained based on data blocks in different rows and different columns.

16. The method of claim 11, wherein the first number of diagonal parity blocks in the set of diagonal parity blocks is less than a second number data blocks in 1.

17. The method of claim 11, wherein a total number of row parity blocks and diagonal parity blocks is less than a first number of data blocks in two columns.

18. The method of claim 11, further comprising:
determining that one or more data blocks of a set of data blocks comprises one or more errors; and
recovering the one or more data blocks based on one or more of:
a first subset of the set of data blocks;
a second subset the set of diagonal parity blocks; and
a third subset of the set of row parity blocks.

19. The method of claim 18, wherein a total number of blocks used to recover the one or more data blocks is less than a remaining number of blocks.

20. non-transitory machine-readable medium having instructions stored therein, which when executed by a processor, cause the processor to perform operations comprising:
obtaining a configuration data, wherein the configuration data indicates:
a logical arrangement for a set of blocks, wherein the logical arrangement comprises rows and columns of blocks;
a number of row parity blocks in a set of row parity blocks; and
a number of diagonal parity blocks in a set of diagonal parity blocks; and
configuring a set of storage devices based on the configuration data, wherein a first number of diagonal parity blocks in the set of diagonal parity blocks is less than a second number of data blocks in a column.
